(19) United States
(12) Patent Application Publication
(10) Pub. No.: US 2003/0096504 A1
(43) Pub. Date: May 22, 2003

(54) Method of dry etching for fabricating semiconductor device

(76) Inventors: Hyun-Kyu Ryu, Ichon-shi (KR); Yun-Seok Cho, Ichon-shi (KR)

Correspondence Address: JACOBSON HOLMAN, PLLC, 400 Seventh Street, N.W., Washington, DC, 20004-2218, US

(21) Appl. No.: 10/294,029

(22) Filed: Nov. 14, 2002

(30) Foreign Application Priority Data
Nov. 19, 2001 (KR) 2001-0071839

(51) Int. Cl. H01L 21/311

(52) U.S. Cl. 438/694

(57) ABSTRACT

The present invention provides a method of dry etching capable of improving an etch selectivity of an etch target against a photoresist pattern during a process for etching a dielectric layer. The inventive method includes the steps of: forming an etch target layer on a substrate; forming a photoresist pattern on the etch target layer; and etching etch target layer by using the photoresist pattern as an etch mask and a mixed gas of C₄F₆ and CH₂F₂.

### FIELD OF THE INVENTION

The present invention relates to a method for fabricating a semiconductor device; and, more particularly, to a method of dry etching for fabricating a semiconductor device capable of performing an etching with a high etching selectivity.

### DESCRIPTION OF RELATED ARTS

As micronization of a semiconductor device has been progressed in today, the importance of lithography and etching technologies has been proportionally emphasized as well. There have been various studies related to those technologies such as a light source of the lithography, a material for a mask, an etching gas and so on.

A wet etching method using a certain solution and a dry etching method using an etching gas are mainly employed for the etching technology. A reactive ion etching (RIE) method has been used in processes for forming semiconductor device. Because of this RIE method, it is possible to fabricate a very highly integrated semiconductor device.

As shown in the above, the etching technology has been grown with the micronization of the semiconductor device. However, a basic photolithography technology for forming a photoresist pattern, which is used as a mask for etching a target layer, has not been changed.

FIGS. 1A to 1B are cross-sectional views showing a method of dry etching in accordance with a prior art.

Referring to FIG. 1A, a dielectric layer 12 is formed on a substrate 11, and a photoresist is subsequently coated on the dielectric layer 12 and patterned through a photo exposure process and a developing process so to form a photoresist pattern 13. Herein, the dielectric layer 12 can be formed with SiO₂, tetra ethyl ortho silicate (TEOS), borophospho silicate glass (BPSG) and so forth.

Referring to FIG. 1B, the dielectric layer 12 is etched by using the photoresist pattern 13 as an etch mask, thereby forming a contact hole 14.

However, this conventional method has a problem in that the photoresist pattern 13 cannot fully resist the etching, which continues until completely opening the contact hole 14, due to the facts that an aspect ratio of the contact hole 14 increases and the photoresist pattern 13 becomes thinner as the semiconductor device is micronized.

As seen from FIG. 1B, the photoresist pattern 13 is also etched during the formation of the contact hole 14. Hence, an undesired portion of the dielectric layer 12 is also etched because of losses of the photoresist pattern 13 through the etching.

As described above, the photoresist pattern 13, which is used as an etch mask, becomes thinner as the micronization of the semiconductor device has been progressively proceeded. Because of the thin photoresist pattern 13, periphery sides of the photoresist pattern 13 are also etched while etching an etch target with the RIE method. As a result, the photoresist pattern 13 cannot fully function as an etch mask. This phenomenon appears more prominently when forming a trench and a contact hole with a high aspect ratio, and becomes a cause for reducing yields of semiconductor devices and deteriorating functions of the semiconductor device.

Therefore, a hard mask is employed to get rid of an effect resulted from the loss of the photoresist pattern designated to be used as an etch mask.

However, compared to the use of the photoresist pattern, this usage of the hard mask is disadvantageous of increased manufacturing costs and total output through (TAT) due to increased number of layers and steps needed to etch a dielectric layer for the hard mask.

Meanwhile, a mixed gas of carbon and fluorine is used as an etch gas for etching the dielectric layer. Such gases as CF₄, CHF₃, CH₂F₂, CH₃F, C₂F₆, and C₃F₈ are examples of the etching gas. However, these gases do not have good etch selectivity against the photoresist pattern. Therefore, the photoresist pattern used as an etch mask for forming the hard mask is also damaged.

For this reason, there developed recently C₄F₈ and C₄F₆ gas and applied to various processes as the etch gas. However, these etching gases have still a limitation in increasing an etch selectivity of an etch target against the photoresist pattern.

### SUMMARY OF THE INVENTION

It is, therefore, an object of the present invention to provide a method of dry etching of a semiconductor device able to improve an etch selectivity of an etch target against a photoresist pattern during an etching process applied to a dielectric layer.

In accordance with an aspect of the present invention, there is provided a method of fabricating a semiconductor device, including the steps of: forming an etch target layer on a substrate; forming a photoresist pattern on the etch target layer; and etching etch target layer by using the photoresist pattern as an etch mask and a mixed gas of C₄F₆ and CH₂F₂.

In accordance with another aspect of the present invention, there is also provided a method of fabricating a semiconductor device, including the steps of: forming a dielectric layer on a substrate; forming a first photoresist pattern on the dielectric layer; etching a part of the dielectric layer with use of the photoresist pattern as an etch mask and a mixed gas of C₄F₆ and CH₂F₂ mixed, wherein a second photoresist pattern having portions covered with polymer is obtained; and forming a contact hole by etching the dielectric layer using the second photoresist pattern as an etch mask.

In accordance with still another aspect of the present invention, there is also provided a method of fabricating a semiconductor device, including the steps of: forming a first nitride-based dielectric layer on a substrate; forming a second oxide-based dielectric layer on the first nitride-based dielectric layer; forming a photoresist pattern on the second oxide-based dielectric layer; etching the second oxide-based dielectric layer until stopping an etching process at the first nitride-based dielectric layer by using the photoresist pattern as an etch mask and a mixed gas of C₄F₆ and CH₂F₂; and exposing a predetermined surface of the substrate by etching the first nitride-based oxide layer.

Preferably, when etching the first nitride-based dielectric layer and the second oxide-based dielectric layer, the C₄F₆ gas is inputted with a flow quantity ranging from about 20 sccm to about 30 sccm, and the mixing ratio of C₄F₆: CH₂F₂ is 1:0.8-1:1.1.

Also, O₂ and Ar gas are added to the mixed gas of C₄F₆ and CH₂F₂ gas. The O₂ gas is added with a flow quantity ranging from about 20 sccm to about 30 sccm, while the Ar gas is added with a flow quantity ranging from about 400 sccm to about 700 sccm.

Also, the first nitride-based dielectric layer and the second oxide-based dielectric layer are etched at a temperature ranging from about −20° C. to about −10° C., a power ranging from about 1700 W to about 1900 W and a pressure ranging from about 30 mTorr to about 50 mTorr. Additionally, the etch selectivity against the photoresist pattern increases as the power and the pressure descend but the temperature conversely ascends.

### BRIEF DESCRIPTION OF THE DRAWING(S)

The above and other objects and features of the present invention will become apparent from the following description of the preferred embodiments given in conjunction with the accompanying drawings, in which:

FIGS. 1A and 1B are cross-sectional views illustrating a method of dry etching of a semiconductor device in accordance with a prior art;

FIGS. 2A and 2B are cross-sectional views illustrating a method for dry etching of a semiconductor device in accordance with a first preferred embodiment of the present invention;

FIGS. 3A and 3B are cross-sectional views illustrating a method of dry etching of a semiconductor device in accordance with a second preferred embodiment of the present invention;

FIG. 4 is a diagram that shows a comparative characteristic of an etch selectivity against a photoresist pattern in accordance with a fraction ratio of a fluorocarbon (F/C) and an etchant used in the prior art and the present invention;

FIG. 5 is a diagram showing a comparative characteristic of the etch selectivity against the photoresist pattern in accordance with a power of the first preferred embodiment;

FIG. 6 is a diagram showing a comparative characteristic of the etch selectivity against the photoresist pattern in accordance with a pressure of the first preferred embodiment of the present invention;

FIG. 7 is a diagram showing a comparative characteristic of the etch selectivity against the photoresist pattern in accordance with a temperature of the first preferred embodiment of the present invention;

FIG. 8 is a diagram showing a comparative characteristic of the etch selectivity against the photoresist pattern in accordance with a flow quantity of oxygen used in the first preferred embodiment of the present invention; and

FIGS. 9A to 9D are cross-sectional views showing another types of contact hole to which the first and the second preferred embodiments of the present invention are applied.

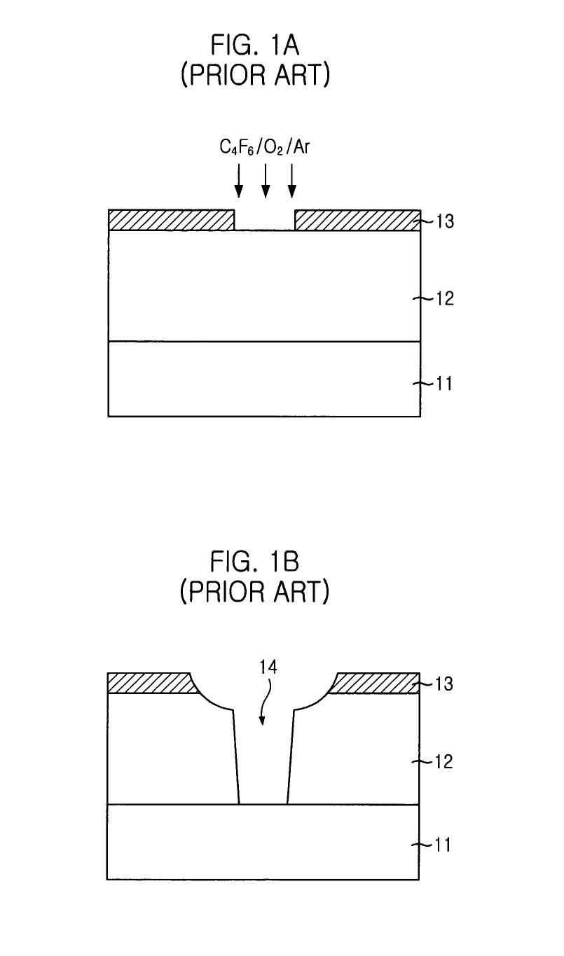

### DETAILED DESCRIPTION OF THE INVENTION

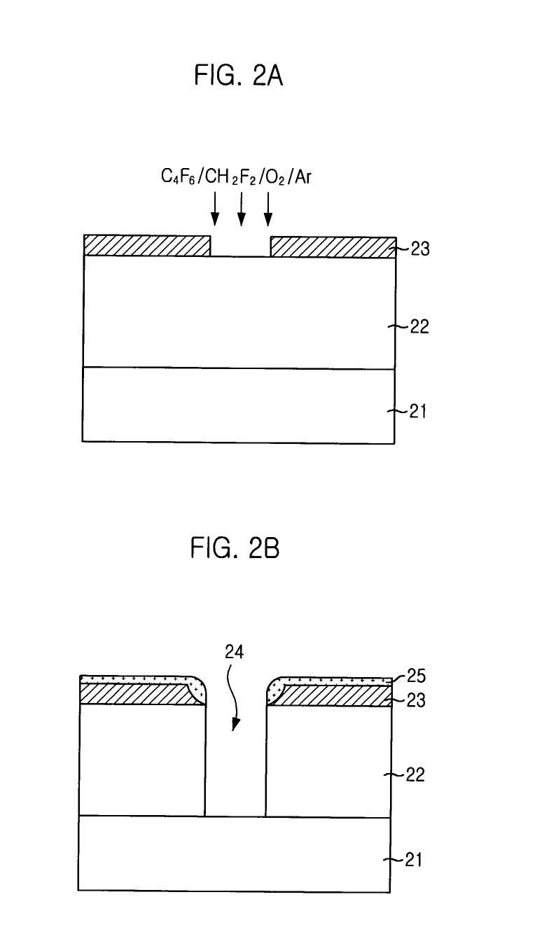

FIGS. 2A and 2B are cross-sectional views illustrating a method of dry etching of a semiconductor device in accordance with a first preferred embodiment of the present invention.

Referring to FIG. 2A, a SiO₂ layer 22 for a dielectric layer is formed on a substrate 21. Then, a photoresist is coated thereon and patterned through a photo exposure and a developing processes so to form a photoresist pattern 23 that exposes an etching area of the SiO₂ layer 22.

With reference to FIG. 2B, a contact hole 24 that exposes the substrate 21 is formed by etching the SiO₂ layer 22 through a reactive ion etching (RIE) that uses the photoresist pattern 23 as an etch mask and an etchant obtained by mixing C₄F₆ based plasma with CH₂F₂ as an etching gas.

At this time, the use of CH₂F₂ as the etching gas leads a bottom portion of the contact hole 24 to be etched while a top portion of the photoresist pattern 23 is deposited with a reaction product 25 such as a polymer. This deposition of the reaction product 25 prevents the photoresist pattern 23 from being etched. Accordingly, it is possible to form the contact hole 24 with a high aspect ratio without losing the photoresist pattern 23 used as an etch mask.

Herein, the CH₂F₂ etching gas enhances a polymerization reaction of a CF₂ radical decomposed from the C₄F₆. Also, the etch selectivity against the photoresist pattern is improved more than twice of the original one by letting a large amount of the F/C to be added to the polymer.

Meanwhile, Ar and O₂ gas are added to the etchant obtained by mixing CH₂F₂ and C₄F₆. Herein, an amount of the Ar gas added ranges from about 400 sccm to about 700 sccm, and that of the O₂ gas ranges from about 20 sccm to about 30 sccm. Also, the C₄F₆ gas is added with a flow quantity ranging from about 20 sccm to about 30 sccm, and the mixing ratio of C₄F₆: CH₂F₂ is 1:0.8-1:1.1. This mixing ratio provides an improvement on the etch selectivity against the photoresist pattern.

Additionally, the RIE to the SiO₂ layer 22 is performed at a temperature ranging from about −20° C. to about −10° C., a power ranging from about 1700 W to about 1900 W and a pressure ranging from about 30 mTorr to about 50 mTorr.

In addition to the SiO₂ layer 22, the RIE is applicable for one of other types of the dielectric layer selected from a group of tetra ethyl ortho silicate (TEOS), borophospho silicate glass (BPSG), a high density plasma (HDP) oxide layer, a low pressure (LP) nitride layer and a plasma enhanced (PE) nitride layer or a stacked layer of these listed layers.

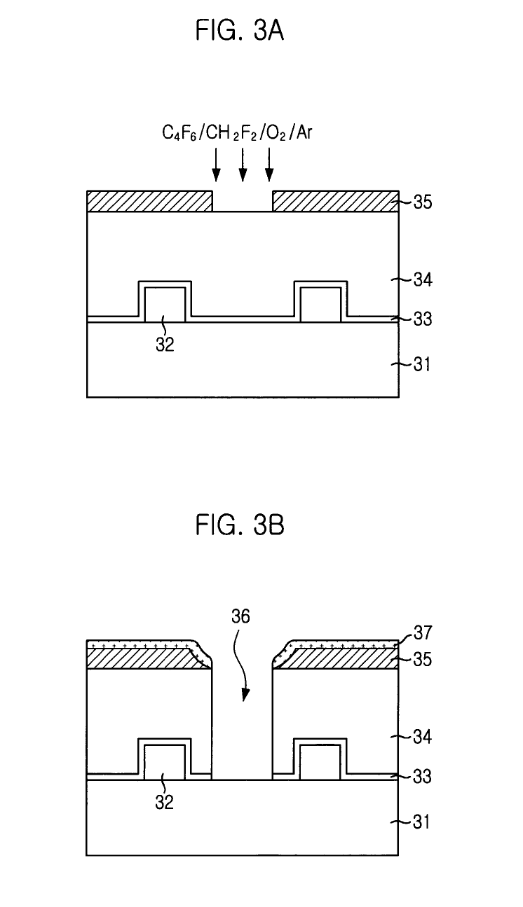

FIGS. 3A and 3B are diagrams for describing a method of dry etching in accordance with a second preferred embodiment of the present invention.

As seen from FIG. 3A, a conductive pattern 32 such as a gate electrode is formed on a substrate 31 and a SiN layer 33 is subsequently formed on the substrate 31 including the conductive pattern 32.

Continuously, a SiO₂ layer 34 is formed on the SiN layer 33, and a photoresist is coated thereon to form a contact hole 36 that reaches the substrate 31 allocated between the conductive patterns 32. Then, the photoresist is patterned through a photo exposure and a developing processes so to form a photoresist pattern 35, which is used as an etch mask for forming the contact hole 36.

With reference to FIG. 3B, it is set to etch the SiO₂ layer 34 by using the photoresist pattern 35 as the etch mask but to stop the etching process at the SiN layer 33. That is, the SiN layer 33 is used an etching stop layer.

At this time, a bottom portion of the photoresist pattern 35 where the SiN layer 33 is revealed is proceeded with the etching process. On the other hand, at a top portion of the photoresist pattern 35, a reaction product 37 such as polymer is deposited, thereby preventing the photoresist pattern 35 from being etched.

Herein, CH₂F₂ gas enhances a polymerization reaction of a CF₂ radical decomposed from C₄F₆ gas. Also, an etch selectivity of an etch target against the photoresist pattern is improved more than twice of the original one by letting a large amount of the F/C to be added to the polymer.

Meanwhile, Ar and O₂ gas are added to a mixed gas of the CH₂F₂ and the C₄F₆. Herein, an amount of the Ar gas added ranges from about 400 sccm to about 700 sccm, and that of the O₂ gas ranges from about 20 sccm to about 30 sccm. Also, the C₄F₆ gas is added with a flow quantity ranging from about 20 sccm to about 30 sccm, and the mixing ratio of C₄F₆: CH₂F₂ is 1:0.8-1:1.1. This mixing ratio improves the etch selectivity against the photoresist pattern. Moreover, the RIE to the SiO₂ layer 34 is performed at a temperature ranging from about −20° C. to about −10° C., a power ranging from about 1700 W to about 1900 W and a pressure ranging from about 30 mTorr to about 50 mTorr.

In addition to the SiO₂ layer 34, the RIE is applicable for one of other types of the dielectric layer selected from a group of tetra ethyl ortho silicate (TEOS), borophospho silicate glass (BPSG), a high density plasma (HDP) oxide layer, a low pressure (LP) nitride layer and a plasma enhanced (PE) nitride layer or a stacked layer of these listed layers.

Next, the SiN layer 33 is etched with the same condition for etching the SiO₂ layer 34 to completely open a contact hole 36 that exposes the substrate 31 allocated between the conductive patterns 32. At this time, the RIE method is applied to etch the SiN layer 33 and the SiO₂ layer 34.

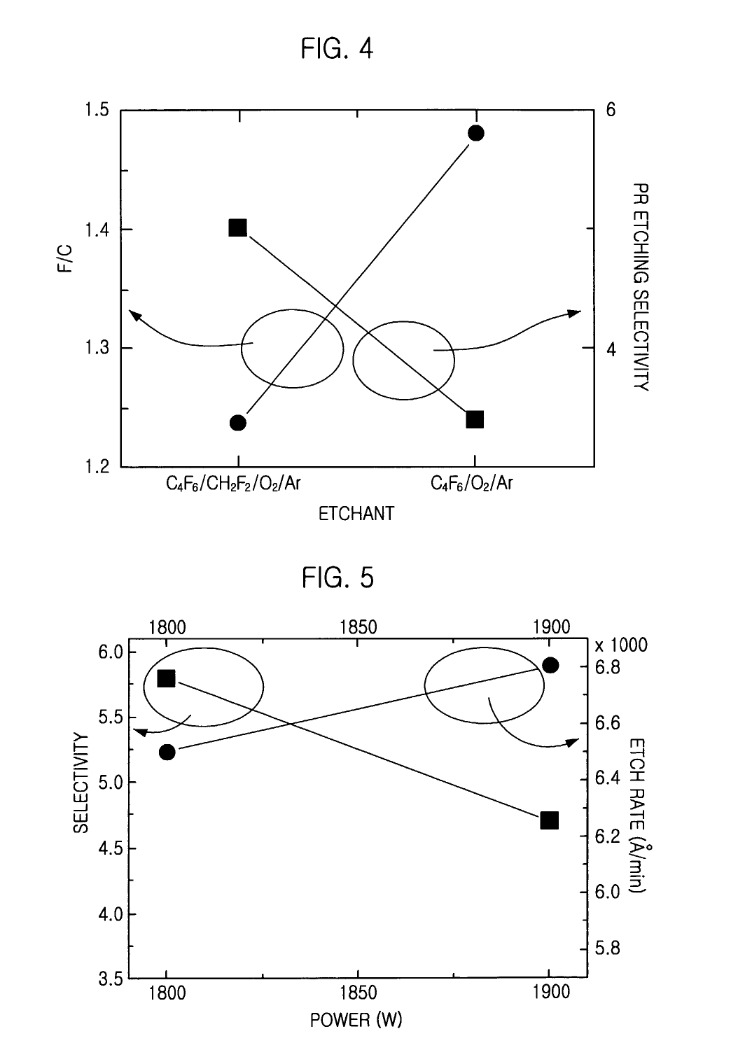

FIG. 4 is a diagram showing a comparative characteristic of an etch selectivity against the photoresist pattern in accordance with a fraction ratio of the F/C and an etchant used in the prior art and the present invention. The mixed gas of C₄F₆, CH₂F₂, O₂ and Ar increases the etch selectivity of an etch target against the photoresist pattern as the fraction ratio of the F/C increases. The increased etch selectivity is approximately 6. Also, the mixed gas of C₄F₆, O₂ and Ar increases the etch selectivity of the etch target against the photoresist pattern as the fraction ratio of the F/C increases. Herein, the increased etch selectivity is approximately 5.

However, in case of using the C₄F₆/O₂/Ar as an etchant, there is a limitation in increasing the fraction of the F/C and the etch selectivity against the photoresist pattern. Contrarily, use of the C₄F₆/CH₂F₂/O₂/Ar as the etchant has an effect of increasing substantially the etch selectivity against the photoresist pattern.

This effect means that the fraction ratio of the F/C increases as a ratio of the CH₂F₂ of the mixed gas becomes higher, resulting in a consequent increase of the etch selectivity against the photoresist pattern.

FIG. 5 is a diagram showing a comparative characteristic of an etch selectivity against the photoresist pattern in accordance with a power (W) of a first preferred embodiment of the present invention. Since the etch selectivity against the photoresist pattern decreases as the power supplied during an etching process increases, the power ranging from about 1700 W to about 1900 W is preferably supplied.

However, in case that the supplied power is below about 1700 W, there arises a problem of irregular etching occurring at edges and a central portion of the substrate. On the other hand, in case that the supplied power is above about 1900 W, there occur damages to an etching equipment, e.g., a chamber itself is etched.

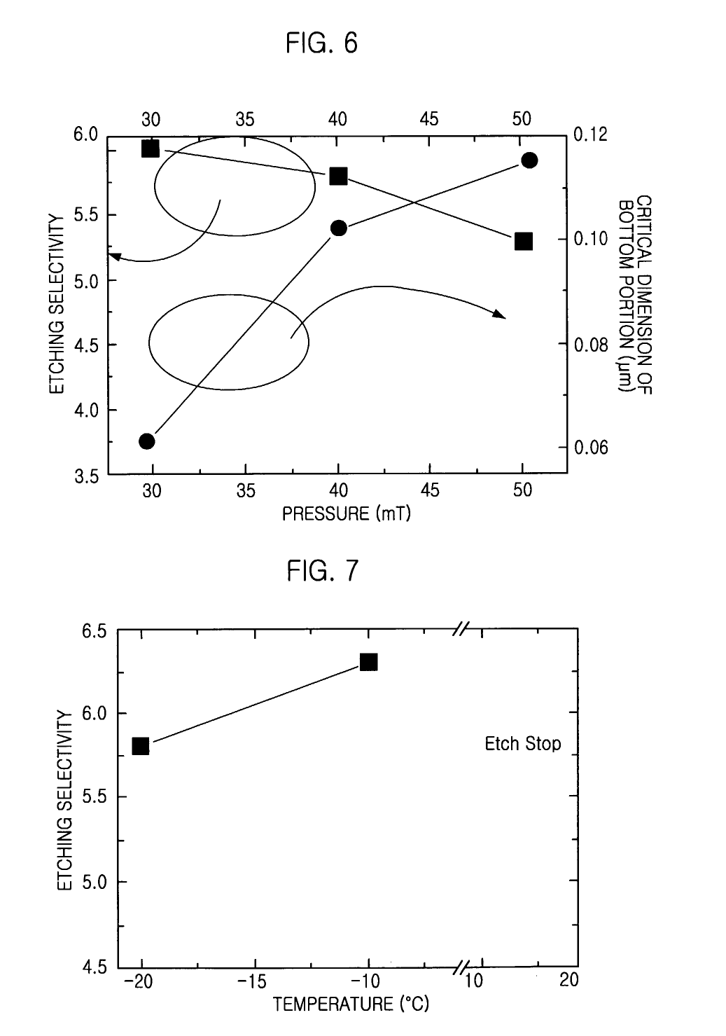

FIG. 6 is a diagram showing a comparative characteristic of an etch selectivity against the photoresist pattern in accordance with a pressure (mTorr) of the first preferred embodiment of the present invention. Since the etch selectivity of an etch target against the photoresist pattern decreases as a pressure increases during the etching process, it is preferable to maintain a pressure within a range from about 30 mTorr to about 50 mTorr.

Meanwhile, as the pressure increases, a critical dimension (hereinafter referred as to CD) of a bottom portion of the contact hole increases. At this time, the etch selectivity and the CD have an inverse relationship. That is, a higher etch selectivity results a lower CD, meaning that a micronized contact hole can be formed. Conversely, a lower etch selectivity results a higher CD, and thus, it is impossible to form the micronized contact hole.

Also, as the pressure decreases, a direct motion of an ion is improved, thereby providing a vertical profile in more extents.

FIG. 7 is a diagram showing a comparative characteristic of an etch selectivity against the photoresist pattern in accordance with a temperature of the first preferred embodiment of the present invention. The etch selectivity of an etch target increases as the temperature increases during the etching process. Hence, the temperature is preferably maintained within a range from about −20° C. to −10° C.

As the temperature increases, an amount of deposited carbon clusters increases as well. This relationship results in a higher etch selectivity against the photoresist pattern. However, if the temperature rises above −10° C., properties of the photoresist pattern used as an etch mask becomes poor. For instance, an improvement on the etch selectivity against the photoresist pattern is remarkable at a temperature of 10° C. In contrast, there occurs an etch stop phenomenon due to poor properties of the photoresist pattern when the temperature rises above −10° C. In other words, the increase of the temperature causes the photoresist pattern to be burned.

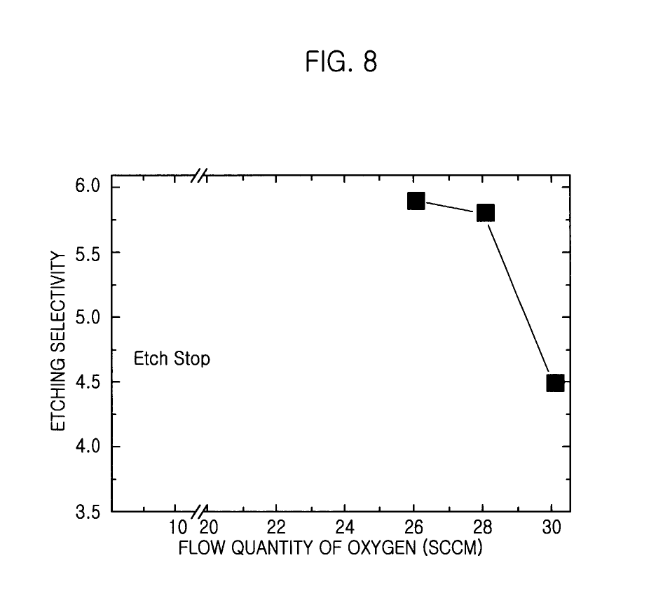

FIG. 8 is a diagram showing a comparative characteristic of an etch selectivity against the photoresist pattern in accordance with a flow quantity of oxygen used in the first preferred embodiment of the present invention. Since the etch selectivity decreases as the flow quantity of oxygen increases, the flow quantity of the oxygen is preferably in a range from about 20 sccm to about 30 sccm.

In case that the flow quantity of the oxygen is below 20 sccm, there occurs an etch stop due to insufficient removal of carbon clusters deposited within the contact hole.

Based on FIGS. 5 to 8, it is clear that the pressure inside of the chamber, the power supplied and the temperature are factors that increase the etch selectivity against the photoresist pattern in addition to the etching gas.

As shown in the first and the second preferred embodiments of the present invention, the reaction product is able to suppress the etching of the photoresist pattern due to a reaction of the etching gas. Such typically used etching gas as CF₄, CHF₃, CH₂F₂, CH₃F, C₂F₆, and C₃F₈ become a plasma state within the vacuum chamber due to discharge of a magnetron. A contributive etching ratio of an ion (or a radical) within the plasma descends in an order of CH₃⁺(CH₃*), CH₂⁺(CH₂*), CF⁺(CF*) and C(C*). It is generally known that the reaction product is easily deposited as the contributive etching ratio descends.

The CH₂F₂ gas can easily contain an unsaturated species compared to F family of CF₄, CHF₃, CH₂F₂, CH₃F, C₂F₆, C₃F₈ and so on, and this unsaturated species becomes a precursor to be deposited as a reaction product, which suppresses the etching as simultaneously as produces an active species that enacts as an etchant.

CF⁺ or C, which becomes the unsaturated species, has a short lifetime, and thus, collides onto a surface of an etch target so as to be deposited as the reaction product. On the other hand, CF₂⁺ can reach a bottom of the etch target due to an extended lifetime. Therefore, it is possible to etch solely the bottom of the contact hole or the trench.

Although the active species, which contributes to the etching process, exists on the surface of the etch target, there exist a substantial number of the unsaturated species on the surface of the etch target. Therefore, the deposition of the reaction product by the unsaturated species is more dominant than the etching by the active species. As a result of this tendency, at the surface of the etch target, the etching process is not proceeded because of the reaction product deposited by the unsaturated species, while the bottom of the trench or the contact hole is proceeded with the etching process.

Consequently, as described in the first and the second preferred embodiment of the present invention, in case of forming a contact hole by etching a dielectric layer such as SiO₂ by using the mixed gas of C₄F₆ and CH₂F₂, the etch selectivity against the photoresist pattern, which is used as an etch mask, increases more than twice of the original one. Also, O₂ and Ar gas are added to prevent enlargement of a top portion of the contact hole and the etch stop phenomenon.

That is, the added O₂ gas reacts with the carbon clusters to produce CO or CO₂ gas, which are discarded through a pumping unit within the chamber. Accordingly, since it is possible to discard the carbon clusters deposited within the contact hole where the etching process is proceeded, it is further possible to control the etch stop phenomenon occurring in the middle of the etching process.

The O₂ gas can be an efficient agent for controlling the etch stop phenomenon when proceeding the etching process at a contact hole of which depth is deeper.

Such inert gas as Ar is supplied to reduce a faction ratio of carbon within the chamber. As the fraction ratio of carbon within the chamber increases, an amount of the carbon clusters also increases. This increased amount of the carbon clusters further leads an inner contact hole to be increasingly deposited with the carbon clusters, and there finally occurs the etch stop phenomenon when the amount of the carbon clusters reaches beyond a set-point. For this reason, it is required to maintain an appropriate fraction ratio of carbon in order to control the undesired etch stop phenomenon. Hence, the inert Ar gas is supplied to maintain the fraction ratio of carbon in an appropriate level.

The RIE, in accordance with the present invention, uses such devices as a magnetron RIE device, an electron cyclotron resonance (ECR) etching device that produces highly dense plasma through a magnetic field and a negative wave by using ECR, a helicon wave etching device that produces highly dense plasma through a mutual effect between a helicon wave and an electron and an induced combining plasma etching device that produces plasma by accelerating an electron through an induced electric field generated by a high frequency inducing device.

Such SiO₂ layer for the dielectric layer is not merely limited to the substrate. Indeed, it can be applicable for polysilicon, silicide and a word line. The etching process to the dielectric layer with use of the C₄F₆ and CH₂F₂ etching gas can also be applicable for other etching processes to a bit line contact and a metal contact.

The first and the second preferred embodiments of the present invention describe only an example of a silicon oxide layer or a double layer of a silicon oxide and a silicon nitride layer. However, the present invention can also apply to other various types of layers such as an oxide layer including impurities or a triple layer of an oxide layer, a nitride layer and another oxide layer.

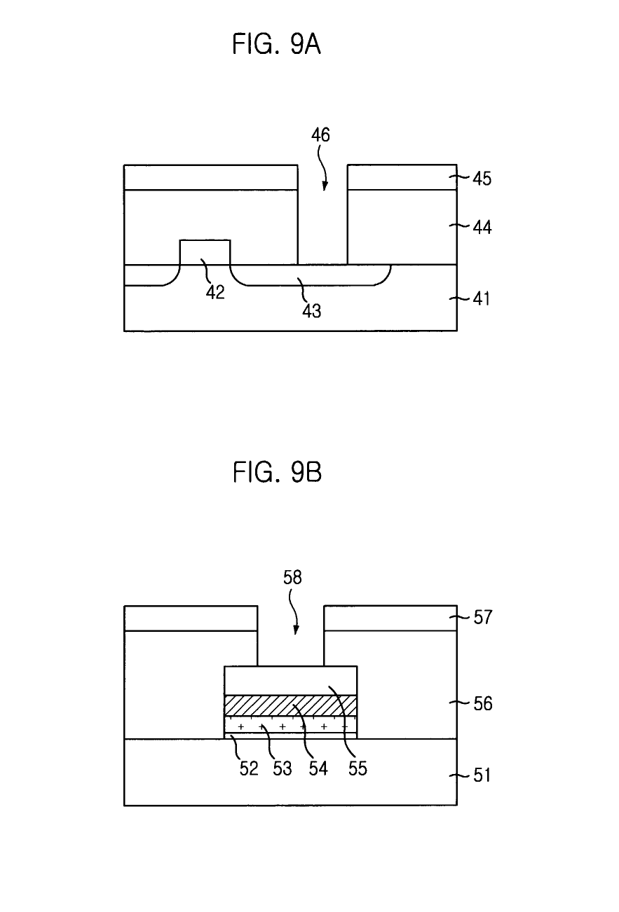

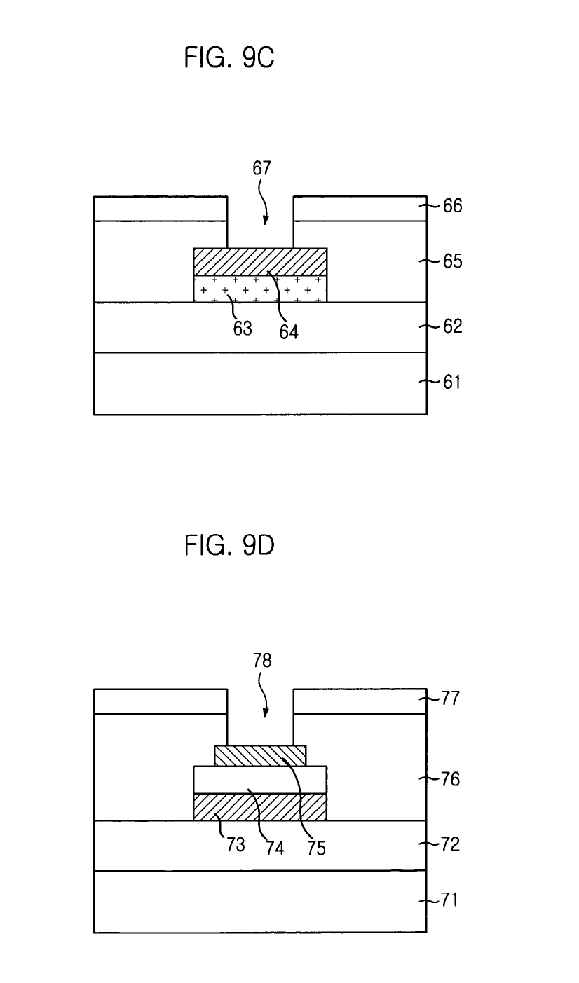

FIGS. 9A to 9D are diagrams illustrating other preferred embodiments of the contact hole to which the present invention can be applied.

Referring to FIG. 9A, a contact hole 46 that exposes a source/drain area 43 at one side of a gate electrode 42 included in a substrate 41 is formed by passing through a silicon oxide layer 44 with use of a photoresist pattern 45 as an etch mask.

The contact hole 46 is formed for forming a contact for connecting the source/drain area 43 to a metal line.

Referring to FIG. 9B, a silicon oxide layer 56 that covers a gate stack formed by stacking sequentially a gate insulating layer 52, a polysilicon layer 53, a metal silicide layer 54 and a capping layer 55 is formed on a substrate 51. Afterwards, a photoresist pattern 57 having a specific opening unit is formed on the silicon oxide layer 56. At this time, the capping layer 55 is either an oxide-based or a nitride-based layer.

Subsequently, the silicon oxide layer 56 and the capping layer 55 is sequentially etched by using the photoresist pattern 57 as an etch mask so as to form a contact hole 58 that exposes the metal silicide layer 54.

As seen from the above, the contact hole 58 can be formed to form a contact for wiring a word line.

With reference to FIG. 9C, an inter-layer insulating layer 62 is formed on a substrate 61, and a bit line pattern is formed on the inter-layer insulating layer 62 thereafter. Herein, the bit line pattern is formed by sequentially stacking a polysilicon layer 63 and a metal silicide layer 64.

After the formation of the bit line pattern, a silicon oxide layer 65 that completely covers the bit line pattern is formed. Then, a photoresist pattern 66 having a particular opening unit is formed on the silicon oxide layer 65.

Next, the silicon oxide layer 65 is etched with use of the photoresist pattern 66 as an etch mask so as to form a contact hole 67 that exposes a predetermined surface of the metal silicide layer 64.

The contact hole 67 can be formed to form a contact for wiring a bit line.

Referring to FIG. 9D, on a substrate 71, an inter-layer insulating layer 72 is formed, and a capacitor including a storage electrode 73, a dielectric layer 74 and a plate electrode 75 is formed thereon. A silicon oxide layer 76 that covers completely the capacitor is then formed.

On the silicon oxide layer 76, a photoresist pattern 77 having a particular opening unit is formed. Thereafter, the silicon oxide layer 76 is etched by using the photoresist pattern 77 as an etch mask so as to form a contact hole 78 that exposes a predetermined surface of the plate electrode 75.

The contact hole 78 can be formed to form a contact for wiring the plate electrode 75.

As clearly illustrated in FIGS. 9A to 9D, these contact holes are formed for different purposes. Therefore, a thickness of each etch target is different as well. Also, it is still possible to employ the mixed gas of C₄F₆ and CH₂F₂ used as the etching gas in the first and the second preferred embodiment of the present invention to form the contact hole used for different purposes. Ultimately, even without employing a hard mask, a level of process completeness can be enhanced by increasing the etching selectivity.

By following the provided preferred embodiments of the present invention, it is possible to improve the etch selectivity of an etch target against the photoresist pattern by stimulating generations of the reaction product with an addition of the CH₂F₂ gas as an etching gas when proceeding an etching process of the dielectric layer by using the photoresist pattern as an etch mask.

Also, since such processes for depositing, removing and etching of a hard mask can be omitted, the present invention provides an effect of reducing fabrication costs. This effect further results in an improvement on completeness of a contact etching process and a wiring process.

While the present invention has been described with respect to certain preferred embodiments, it will be apparent to those skilled in the art that various changes and modifications may be made without departing from the scope of the invention as defined in the following claims.

What is claimed is:

1. A method of fabricating a semiconductor device, comprising the steps of:
forming an etch target layer on a substrate;
forming a photoresist pattern on the etch target layer; and
etching etch target layer by using the photoresist pattern as an etch mask and a mixed gas of C₄F₆ and CH₂F₂.

2. The method as recited in claim 1, wherein the C₄F₆ gas is used with a flow quantity ranging from about 20 sccm to about 30 sccm and a mixing ratio of C₄F₆:CH₂F₂ is 1:0.8-1:1.1.

3. The method as recited in claim 1, wherein the step of forming the etching the etch target layer further includes the step of adding O₂ gas and Ar gas to the mixed gas of C₄F₆ and CH₂F₂.

4. The method as recited in claim 3, wherein the Ar gas is added with a flow quantity ranging from about 400 sccm to about 700 sccm, while the O₂ gas is added with a flow quantity ranging from about 20 sccm to about 30 sccm.

5. The method as recited in claim 1, wherein the step of etching the etch target layer is carried out at a temperature ranging from about −20° C. to about −10° C., a power ranging from about 1700 W to about 1900 W and a pressure ranging from about 30 mTorr to about 50 mTorr.

6. A method of fabricating a semiconductor device, comprising the steps of:
forming a dielectric layer on a substrate;
forming a first photoresist pattern on the dielectric layer;
etching a part of the dielectric layer with use of the photoresist pattern as an etch mask and a mixed gas of C₄F₆ and CH₂F₂ mixed, wherein a second photoresist pattern having portions covered with polymer is obtained; and
forming a contact hole by etching the dielectric layer using the second photoresist pattern as an etch mask.

7. The method as recited in claim 6, wherein the C₄F₆ gas is used with a flow quantity ranging from about 20 sccm to about 30 sccm and a mixing ratio of C₄F₆: CH₂F₂ is 1:0.8-1:1.1.

8. The method as recited in claim 7, wherein the step of etching the dielectric layer further includes the step of adding O₂ gas and Ar gas to the mixed gas of C₄F₆ and CH₂F₂.

9. The method as recited in claim 8, wherein the Ar gas is added with a flow quantity ranging from about 400 sccm to about 700 sccm and the O₂ gas is added with a flow quantity ranging from about 20 sccm to about 30 sccm.

10. The method as recited in claim 7, wherein the step of etching the dielectric layer is carried out at a temperature ranging from about −20° C. to about −10° C., a power ranging from about 1700 W to about 1900 W and a pressure ranging from about 30 mTorr to about 50 mTorr.

11. A method of fabricating a semiconductor device, comprising the steps of:
forming a first nitride-based dielectric layer on a substrate;
forming a second oxide-based dielectric layer on the first nitride-based dielectric layer;
forming a photoresist pattern on the second oxide-based dielectric layer;
etching the second oxide-based dielectric layer until stopping an etching process at the first nitride-based dielectric layer by using the photoresist pattern as an etch mask and a mixed gas of C₄F₆ and CH₂F₂; and
exposing a predetermined surface of the substrate by etching the first nitride-based oxide layer.

12. The method as recited in claim 11, wherein the step of etching the first nitride-based dielectric layer is carried out with identical conditions of temperature, pressure and power provided for etching the second oxide-based dielectric layer.

13. The method as recited in claim 12, wherein the C₄F₆ gas is inputted with a flow quantity ranging from about 20 sccm to about 30 sccm and the CH₂F₂ of which mixing ratio ranges from about 0.8 to about 1.1 is mixed with the C₄F₆ of which mixing ratio is about 1.

14. The method as recited in claim 12, wherein the mixed gas of C₄F₆ and CH₂F₂ is added with O₂ gas and Ar gas.

15. The method as recited in claim 14, wherein the Ar gas is inputted with a flow quantity ranging from about 400 sccm to about 700 sccm and the O₂ gas is inputted with a flow quantity ranging from about 20 sccm to about 30 sccm.

16. The method as recited in claim 12, wherein the step of etching the first nitride-based dielectric layer and the second oxide-based dielectric layer is carried out at a temperature ranging from about −20° C. to about −10° C., a power ranging from about 1700 W to about 1900 W and a pressure ranging from about 30 mTorr to about 50 mTorr.
